(19) United States
(12) Patent Application Publication
(10) Pub. No.: US 2021/0333444 A1
(43) Pub. Date: Oct. 28, 2021

(54) LIGHT ABSORPTION FILM, PREPARATION METHOD AND APPLICATION

(71) Applicant: NINGBO INSTITUTE OF MATERIALS TECHNOLOGY & ENGINEERING, CHINESE ACADEMY OF SCIENCES, Ningbo City, Zhejiang (CN)

(72) Inventors: Zhenlun SONG, Ningbo City (CN); Abdul Ghafar WATTOO, Ningbo City (CN); Xuefeng DING, Ningbo City (CN); Lijing YANG, Ningbo City (CN); Bichang ZHENG, Ningbo City (CN); Jianjun JIANG, Ningbo City (CN); Fangqin HU, Ningbo City (CN)

(73) Assignee: Ningbo Institute of Materials Technology & Engineering, Chinese Academy of Sciences, Ningbo City, Zhejiang (CN)

(21) Appl. No.: 16/619,175

(22) PCT Filed: Aug. 21, 2018
(86) PCT No.: PCT/CN2018/101468

§ 371 Date: Dec. 12, 2019

(30) Foreign Application Priority Data
Jun. 6, 2018 (CN) 201810575055.3

(51) Int. Cl. G02B 5/00; C23C 14/35; C23C 14/34; C23C 14/06; C23C 14/08; C23C 14/10

(52) U.S. Cl. CPC G02B 5/003; C23C 14/352; C23C 14/3464; G02B 1/113; C23C 14/0676; C23C 14/083; C23C 14/10; C23C 14/0641

(57) ABSTRACT

A light absorption film. The light absorption film is a titanium-aluminum-nitride film, including a bottom layer and an outer layer; the bottom layer has a nano-layered structure, the outer layer has a columnar crystal structure, and the top of the columnar crystal structure is a conical surface; within a light wavelength range of 200 nm to 2500 nm, the light absorption film has an average light absorption rate (α) of not less than 0.89. After adding an antireflection layer of TiAlON, TiO₂ or SiO₂ to the outer layer of the light absorption film, the average light absorption rate (α) is not less than 0.95 within the light wavelength range of 200 nm to 2500 nm. The light absorption film has advantages of such as a wide frequency range for light absorption, a high absorption rate, and stable physical and chemical properties of the film in adverse environments.

### TECHNICAL FIELD

The present application refers to a light absorption film, preparation method and application, belonging to the fields of materials and physical vapor deposition.

### BACKGROUND

A high-performance light absorption film can be widely applied in solar thermal conversion, heat management, internal extinction of optical instruments and so on. A light absorption layer can be produced on the surface of a material by brushing black paint, electrochemical etching and laser processing, but each has its own disadvantage: the paint is prone to degradation and is not wear-resistant, and the etching and laser processing are complicated in procedure. Ti-based coating prepared by magnetron sputtering system is a currently common method for industrial production of light absorption films, which has good light absorption performances within a certain range of spectrum. However, for full-band light absorption, a three-dimensional structure is usually further required.

Therefore, it is of great significance to find a light absorption film with a simple preparation method, chemically and thermally stable for high-temperature performances with a wider spectral frequency range finding potential applications in solar energy conversion, heat control, noise reduction of stray light in optical devices and so on.

### SUMMARY OF THE INVENTION

According to one aspect of the present application, provided is a light absorption film which has advantages such as a wide frequency range for light absorption, a high absorption rate, and stable physical and chemical properties.

The light absorption film is a titanium-aluminum-nitride film, comprising a bottom layer and an outer layer;

the bottom layer has a nano-layered structure, the outer layer has a columnar crystal structure, and the top of the columnar crystal structure is a conical surface;

within a light wavelength range of 200 nm to 2500 nm, the light absorption film has an average light absorption rate (α) of not less than 0.89.

Optionally, the titanium-aluminum-nitride film is a TiAlN ternary black film.

Optionally, within a light wavelength range of 200 nm to 2500 nm, the light absorption film has an average light absorption rate α=0.89.

Optionally, the thickness of the nano-layered structure is ranged from 50 nm to 300 nm; the width of the crystal grain in the columnar crystal structure is ranged from 30 nm to 100 nm, the thickness of the grain boundary between the columnar crystal grains is ranged from 12 nm to 20 nm, and the thickness of the columnar crystal coating layer is ranged from 800 nm to 2000 nm.

Optionally, the thickness of the nano-layered structure is ranged from 80 nm to 150 nm; the width of the crystal grain in the columnar crystal structure is ranged from 50 nm to 70 nm, the thickness of the grain boundary between the columnar crystal grains is ranged from 15 nm to 18 nm, and the thickness of the columnar crystal coating layer is ranged from 800 nm to 1000 nm.

Optionally, the thickness of the nano-layered structure is 100 nm; the width of the crystal grain in the columnar crystal structure is 50 nm, the thickness of the grain boundary between the columnar crystal grains is 17 nm, and the thickness of the columnar crystal coating layer is 1000 nm.

In the present application, the bottom layer has a layered structure, which can provide a better bond between the film and the substrate; the conical surface structure at the top of the columnar crystal structure enables the maximum incident light to enter the structured film; the grain boundary of the columnar structure and the subboundary inside the columnar structure can provide multiple reflections for the incident light to ensure a sufficient absorption of the incident light.

Optionally, the light absorption film further comprises at least one antireflection layer.

Optionally, the antireflection layer is at least one selected from the group consisting of TiAlON, TiO₂—SiO₂ and SiO₂.

Optionally, within a light wavelength range of 200 nm to 2500 nm, the light absorption film has an average light absorption rate (α) of not less than 0.95. The light absorption rate is higher than that of the conventional light absorption film obtained by physical vapor deposition of any ceramic.

Optionally, within a light wavelength range of 200 nm to 2500 nm, the light absorption film has an average light absorption rate α=0.95.

As a preferred embodiment, the bottom layer of the film in the present application has a thickness of about 100 nm and a nano-layered structure; the outer layer of the film has a columnar crystal structure with a thickness of about 1000 nm, the width of the crystal grain in the columnar crystal is 50 nm, and the thickness of the grain boundary between the columnar crystals is about 17 nm; the top of the columnar structure is a conical surface. The constituents of the film is titanium-aluminum-nitride (TiAlN). Within a light wavelength range of 200 nm to 2500 nm, the average light absorption rate of the film is 0.89, and if an oxide antireflection layer (TiAlN/TiAlON/TiO₂—SiO₂) is further added to the surface, the absorption rate can be increased to 0.95, which is higher than that of the conventional light absorption film obtained by physical vapor deposition of any ceramic.

The light absorption coating layer of the present application may be coated on bulk materials and any kind of substrates. The material of the substrate may be metal, glass, silicon wafer, polymer, etc., which has a wide applicable range. The light absorption coating layer has extensive applications in the fields of solar energy conversion, heat control of heating devices, heat control of spacecraft, extinction of optical devices and so on.

According to another aspect of the present application, provided is a method for preparing any one of the aforementioned light absorption films, which is low in cost of raw materials, requires no other special treatments on substrate and coating process, is simple and convenient in process, and can realize a large-area preparation. The light absorption film prepared by the method has a controllable structure, a wide frequency range for light absorption and a high absorption rate, and meanwhile can be coated on the surfaces of substrates of different materials. The physical and chemical properties of the film are stable.

The method for preparing the light absorption film, wherein a magnetron sputtering process is used to apply a co-sputtering of a titanium target and an aluminum target, comprises at least the following steps:

a1) introducing a gas mixture of nitrogen and a non-active gas into a vacuum apparatus, and applying a reverse sputtering to the targets to produce nitrides with a specific thickness, namely a nitriding treatment, the time for the nitriding treatment being ranged from 3 min to 100 min;

b1) after the nitriding treatment is completed, applying a normal sputtering to the targets to form the light absorption film on the surface of a substrate.

Optionally, the non-active gas in step a1) is at least one selected from the group consisting of nitrogen and inert gases.

Optionally, the substrate in step b1) comprises at least one selected from the group consisting of metals, glasses, silicon wafers, single crystal materials and polymer materials.

Optionally, the substrate comprises at least one selected from the group consisting of bulk materials and film materials.

Preferably, the metal comprises at least one selected from the group consisting of copper and stainless steel.

Preferably, the single crystal material comprises at least one selected from the group consisting of single crystal sodium chloride and single crystal silicon.

Preferably, the polymer material comprises at least one selected from the group consisting of polymethyl methacrylate-based materials, polyethylene glycol terephthalate-based materials, polypropylene-based resin materials, polyethylene-based resin materials and polyamide-based materials.

Optionally, the surface of a workpiece is physically washed by the ion source configured in a sputtering system.

Optionally, the method for preparing the light absorption film, wherein the direct current or direct current pulse magnetron sputtering process is used to apply a co-sputtering to a titanium target and an aluminum target, comprises at least the following steps:

a2) introducing a non-active gas at a flow rate ranged from 5 sccm to 200 sccm into a vacuum apparatus having a vacuum degree ranged from 5.0×10⁻⁴ Pa to 9.0×10⁻⁴ Pa until the pressure in the vacuum apparatus reaches a range from 0.01 Pa to 5 Pa, introducing nitrogen at a flow rate ranged from 1 sccm to 200 sccm, and applying a reverse sputtering to the targets to produce nitrides with a specific thickness, namely a nitriding treatment, the time for the nitriding treatment being ranged from 3 min to 100 min;

b2) after the nitriding treatment is completed, applying a normal sputtering to the targets to form the light absorption film on the surface of a substrate.

Preferably, step a2) is: introducing argon gas at a flow rate ranged from 5 sccm to 100 sccm into a vacuum chamber having a vacuum degree of 7.0×10⁻⁴ Pa until the pressure in the vacuum chamber reaches a range from 0.02 Pa to 3 Pa, then introducing nitrogen at a flow rate ranged from 2 sccm to 50 sccm, and applying a normal sputtering to the targets to form the light absorption film on the surface of a substrate, the time for possessing being ranged from 5 min to 60 min.

Optionally, the argon gas is of high-purity of 99.999%.

Optionally, the method for preparing the light absorption film further comprises step c): continuing to deposit at least one antireflection layer on the surface of the light absorption film to obtain a light absorption film comprising the antireflection layer.

As a specific embodiment, the direct current or direct current pulse magnetron sputtering process is used to apply a co-sputtering to a high-purity titanium target and a high-purity aluminum target:

a gas mixture of nitrogen and argon with a predetermined ratio is introduced into a vacuum chamber, and a baffle is employed to apply a reverse sputtering to the targets, so as to produce nitrides on the surfaces of the high-purity titanium target and the high-purity aluminum target; after achieving a certain level of nitrides thickness on the surfaces of targets, the baffle is removed, and a light absorption film is formed on the surface of a substrate by sputtering. A TiAlN bottom layer with a nano-layered structure is formed by co-deposition on the surface of the substrate, and then a TiAlN outer layer with a columnar crystal structure is formed. A high-performance light absorption film, which has a bottom nano-layered structure and an outer layer with a columnar crystal structure, may be obtained on the surface of a substrate by a single coating process.

As another specific embodiment, the direct current or direct current pulse magnetron sputtering process is used to apply a co-sputtering to a high-purity titanium target and a high-purity aluminum target:

a gas mixture of nitrogen and argon gas with a predetermined ratio is introduced into a vacuum apparatus, and a baffle is employed to apply a reverse sputtering to the targets, while the thickness of the nitrides produced on the surfaces of the high-purity titanium target and the high-purity aluminum target is controlled; subsequently, the baffle is opened, and a light absorption film is formed on the surface of a substrate by sputtering; sequentially, at least one antireflection layer is deposited on the surface of the light absorption film to obtain a high light absorption film.

In the present application, in order to ensure that the surface of a substrate is clean, the substrate may be subjected to such as ultrasonic washing and absolute alcohol washing before being coated.

According to still another aspect of the present application, provided is the use of at least one of the aforementioned light absorption films and the light absorption films prepared by the aforementioned methods in the fields of solar energy conversion, heat control and extinction of optical devices.

The beneficial effects of the present application include but are not limited to:

1) The light absorption film provided by the present application has advantages of such as a wide frequency range for light absorption, a high absorption rate and stable physical and chemical properties of the film, and the absorption rate can be increased to 0.95.

2) The light absorption film provided by the present application may be coated on bulk materials and film substrates. The material of the substrate may be metal, glass, silicon wafer, single crystal material, polymer material, etc., which has a wide applicable range. The light absorption film has extensive applications in the fields of solar energy conversion, heat control of heating devices, heat control of spacecraft, extinction of optical devices and so on.

3) The method for preparing the light absorption film provided by the present application may realize a high-performance light absorption film having a bottom layer of a layered nanostructures and an outer layer with a columnar crystal structure on the surface of a substrate by a single coating process; the method is cost effective, requires no other treatments on substrate and coating process, is simple and convenient, and can realize a large-area preparation.

4) The light absorption film prepared by the method for preparing the light absorption film provided by the present application has a controllable structure, a wide frequency range for light absorption and a high absorption rate, and meanwhile can be coated on the surfaces of substrates of different materials. The physical and chemical properties of the film are highly stable.

### DESCRIPTION OF THE FIGURES

FIG. 1(a) is a schematic diagram of the placement of the co-deposition targets in Example 1 of the present application.

FIG. 1(b) is the cross sectional scanning electron microscopy micrograph of the columnar crystal structure of the light absorption film of sample 1^{#} of the present application.

FIG. 1(c) is a scanning electron micrograph of the conical structure at the top of the columnar crystal on the surface of the light absorption film of sample 1^{#} in the Example of the present application.

FIG. 1(d) shows the morphology characterization results by atomic probe microscopy of the light absorption film of sample 1^{#} in the Example of the present application.

FIG. 1(e) shows the morphology characterization results by atomic probe microscopy of the light absorption film of sample 1^{#} in the Example of the present application.

FIG. 1(f) is a real product picture of the light absorption film of sample 1^{#} in the Example of the present application coated on a copper substrate.

FIG. 1(g) is an optical real product picture of the light absorption film of sample 4^{#} in the Example of the present application coated on a polypropylene resin film substrate.

FIG. 2(a) is a transmission electron microscope photograph of the cross-sectional structure of the light absorption film of sample 1^{#} in the Example of the present application showing the nano-layered structure on the bottom and the outer columnar crystal structure.

FIG. 2(b) is a transmission electron microscope photograph of the cross-sectional structure of the light absorption film of sample 1^{#} in the Example of the present application showing subboundary structure inside the columnar crystal.

FIG. 3(a) is a schematic diagram showing the light absorption mechanism in the light absorption film in an embodiment of the present application showing the process of incident light being induced from the surface of the film into the interior of the film.

FIG. 3(b) is a schematic diagram showing the process of light being reflected repeatedly between the grain boundaries to increase absorption.

FIG. 4(a) shows the characterization results of the reflection and absorption performances of the TiAlN film in the present application, showing the total reflection, diffuse reflection and specular reflection of sample 1^{#} after depositing the light absorption film on the surface of a copper substrate, Cu/TiAlN.

FIG. 4(b) is the light absorption spectrum after depositing the light absorption film on the copper substrate and adding an antireflection film (sample 6^{#}: Cu/TiAlN/TiAlON, sample 7^{#}: Cu/TiAlN/TiO₂—SiO₂, sample 8^{#}: Cu/TiAlN/TiAlON/TiO₂—SiO₂), and the inset shows the best light absorption performance corresponding to the wavelength range of 200˜1400 nm.

FIGS. 5(a) to 5(c) are the (a) XRD, (b) Raman spectrum and (c) light absorption spectrum of the light absorption films of sample 1^{#} in the Example of the present application, being untreated and after various treatments.

FIGS. 5(d) to 5(f) show the morphology characterization by scanning electron microscope of the light absorption films of sample 1^{#} in the Example of the present application after various environmental treatments: (d) the surface morphology after 8 hours UV treatment, (e) the surface morphology after 92 hours treatment at 85% humidity, and (f) the surface morphology after 15 periods of thermal shock treatment between −190° C. and 140° C.

FIGS. 5(g) to 5(i) show the scanning probe morphology of the light absorption film of sample 1^{#} in the Example of the present application after various environmental treatments: (g) the scanning probe morphology after UV treatment, (h) the scanning probe morphology after humidity treatment, and (i) the scanning probe morphology after thermal shock treatment.

FIG. 6(a) shows the performance of the light absorption film of sample 3^{#} in the Example of the present application after heating in air, showing the Raman spectrum of the film after the heating.

FIG. 6(b) shows the performance of the light absorption film of sample 3^{#} in the Example of the present application after heating in air showing the light absorption rates of the film after the heating.

### DETAILED DESCRIPTION OF THE EMBODIMENT

The present application is described in detail below with reference to the Examples, but the application is not limited to these Examples.

Unless otherwise stated, the raw materials in the Examples of the present application are all commercially purchased, wherein the targets are: a high-purity titanium target and a high-purity aluminum target with a purity of 99.999%, and the sizes of the targets are: titanium target: Φ100 mm×10 mm, and aluminum target: Φ100 mm×20 mm.

The analyses methods in the Examples of the present application are as follows:

In the Examples, a scanning electron microscope of QUANTA 250 FEG type manufactured by the American company FEI was used for characterizing the cross-sectional morphology of the samples.

X-ray powder diffraction was used for characterizing the structure of the samples, and performed using a D8 Discover powder diffractometer from Bruker AXS, with a Cu Kα radiation source (λ=1.5406 Å).

A transmission electron microscope of Tecnai F 20 type manufactured by the American company FEI was used for the transmission electron microscopic characterization of the samples.

A scanning probe microscope of Dimension 3100V type was used for characterizing the roughness and morphology of the samples.

A UV-vis/NIR spectrophotometer was used for analyzing the light absorption performance of the samples.

A Raman spectrometer manufactured by the Renishaw in Via company was used for characterizing the samples, with a laser source of Nd:YAG and a wavelength of 532 nm.

### Example 1 Preparation of Light Absorption Film

A vacuum apparatus equipped with two or more magnetron sputtering targets was used, wherein the targets were respectively a high-purity titanium target and a high-purity aluminum target with a purity of 99.999%, and the sizes of the targets were: titanium target: Φ100 mm×10 mm, and aluminum target: Φ100 mm×20 mm. The two sputtering targets were connected to two direct current power sources, respectively. The two targets were each inclined by 15° to direct to the coating area together. The distance between the targets and the substrate was 10 cm.

In order to ensure the cleanness of the sample surface, the substrate might be subjected to ultrasonic and absolute alcohol washing before being coated.

Preparation of Sample 1^{#}

Copper was used as the substrate, and the copper substrate was placed in the coating area. The vacuum degree of the vacuum apparatus was applied to 7.0×10⁻⁴ Pa, and high-purity argon gas of 99.999% was introduced at a flow rate of 40 sccm, until the pressure in the vacuum chamber reached around 0.1 Pa. Nitrogen with a flow rate of 18 sccm was introduced, and the baffle was closed to apply a cleaning sputtering to the targets, with the sputtering time being 50 min. At this time, since the targets were blocked, most of the sputtered atoms were reverse sputtered to the surface of the targets by the baffle, and formed a layer of nitrides.

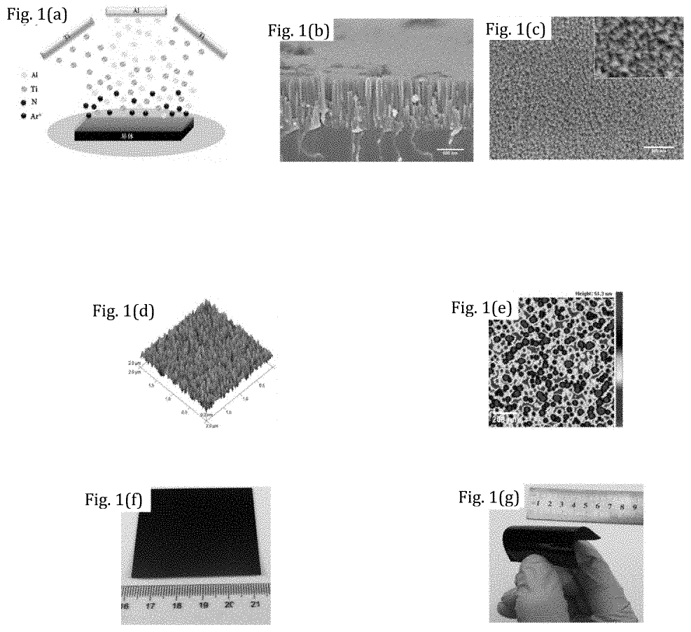

After the thickness of the nitrides on the surfaces of the targets reached a certain level (namely, the cleaning sputtering was finished), the baffle was removed, a TiAlN bottom layer of transition layer with a nano-layered structure was formed by co-deposition on the surface of the workpiece, and then a TiAlN outer layer with a columnar crystal structure was formed, with the sputtering time being 60 min. After completion, the obtained light absorption film was recorded as sample 1^{#} Cu/TiAlN. The schematic diagram of the placement of the co-deposition targets is shown in FIG. 1(a), and the light absorption film coated on the copper substrate is shown in FIG. 1(f).

Preparation of Samples 2^{#} to 4^{#}

The preparation processes of samples 2^{#} to 4^{#} were the same as that of sample 1^{#}, except that the substrate was replaced by glass, single crystal silicon and polypropylene resin film. The light absorption film of sample 4^{#} coated on the polypropylene resin film substrate is shown in FIG. 1(g).

Preparation of Samples 5^{#} to 8^{#}

The preparation process of samples 5^{#} was the same as that of sample 1^{#}, except that another layer of SiO₂ was deposited on the surface of the film subsequently to obtain Cu/TiAlN/SiO₂; wherein the thickness of the SiO₂ layer was around 30 nm, and the target used was a Si target having a purity of 99.999.

The preparation process of sample 6^{#} was the same as that of sample 1^{#}, except that another layer of TiAlON was deposited on the surface of the film subsequently to obtain Cu/TiAlN/TiAlON; wherein the thickness of the TiAlON layer was 30 nm, and the targets used were the same as those for sample 1^{#}.

The preparation process of sample 7^{#} was the same as that of sample 1^{#}, except that another layer of TiO₂—SiO₂ was deposited on the surface of the film subsequently to obtain Cu/TiAlN/TiO₂—SiO₂; wherein the thickness of the TiO₂—SiO₂ layer was 30 nm, and the targets used were pure titanium target, pure aluminum target and pure silicon target.

The preparation process of sample 8^{#} was the same as that of sample 6^{#}, except that another layer of TiO₂—SiO₂ was deposited subsequently on the basis of sample 6^{#}, to obtain Cu/TiAlN/TiAlON/TiO₂—SiO₂; wherein the thickness of the TiAlON layer was 30 nm, the thickness of the TiO₂—SiO₂ layer was 30 nm, and the targets used were pure titanium target, pure aluminum target and pure silicon target.

Preparation of Sample 9^{#}

The preparation process of sample 9^{#} was the same as that of sample 1^{#}, except that before nitrogen was introduced, the surface of the substrate was physically washed by the ion source configured in the sputtering system.

Preparation of Samples 10^{#} and 11^{#}

The preparation process of sample 10^{#} was the same as that of sample 1^{#}, except that a non-active gas was introduced at a flow rate of 120 sccm into the vacuum apparatus having a vacuum degree of 5×10⁻⁴ Pa until the pressure in the vacuum apparatus reached 2 Pa, and nitrogen was introduced at a flow rate of 5 sccm.

The preparation process of sample 11^{#} was the same as that of sample 1^{#}, except that a non-active gas was introduced at a flow rate of 60 sccm into the vacuum apparatus having a vacuum degree of 9.0×10⁻⁴ Pa until the pressure in the vacuum apparatus reached 0.1 Pa, and nitrogen was introduced at a flow rate of 10 sccm.

### Example 2 Structure Characterization of Light Absorption Film

Sample 1^{#} was used as a typical sample, the cross-sectional morphology was characterized by the scanning electron microscopy. As shown in FIG. 1(b) and FIG. 1(c), a columnar crystal structure is clearly observed in FIG. 1(b), and the crystal grains have a width of 30˜50 nm and a thickness of 800˜900 nm, wherein the columnar crystal structures with a crystal grain width of around 50 nm and a thickness of around 900 nm account for a relatively large proportion of around 70%-90%.

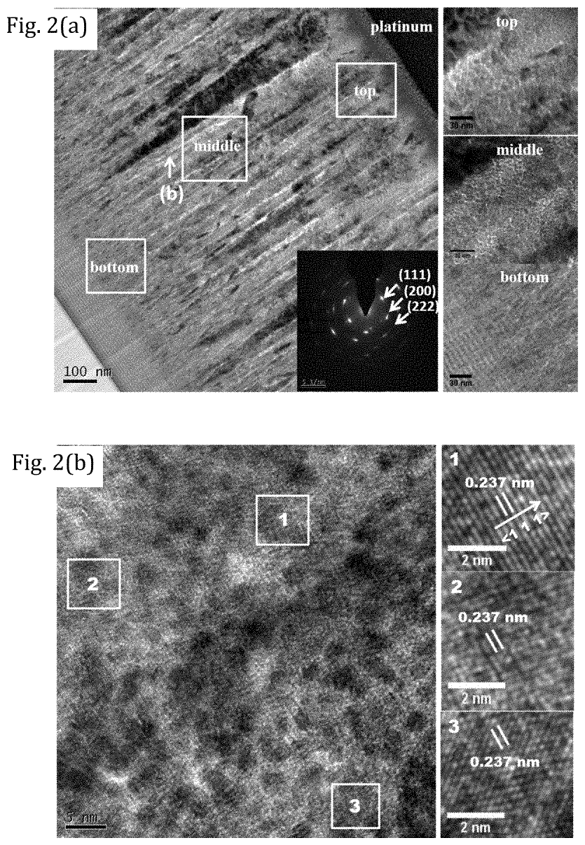

The structure of sample 1^{#} was characterized by the transmission electron microscope. As shown in FIG. 2, a nano-layered structure on the bottom of the sample and an outer columnar crystal structure can be observed in FIG. 2(a), wherein the columnar crystals have a crystal grain width of around 50 nm and a height of around 900 nm; a subboundary structure inside the columnar crystals can be observed in FIG. 2(b), wherein the width of the subboundary is around 0.237 nm.

The structure of sample 1^{#} was characterized by the atomic force microscope. As shown in FIG. 1(d) and FIG. 1(e), the surface of the film prepared shows a rough pyramid shape.

The structures of the other samples are similar to sample 1^{#}.

Structural Characterization of Light Absorption Film after Environmental Treatment

The UV irradiation, humidity treatment and thermal shock treatment were applied to sample 1^{#}, respectively, and the changes in structure and morphology thereof before and after treating were studied.

The condition for UV irradiation was: 8 hours under UV irradiation;

the condition for humidity treatment was: 92 hours treatment at 85% humidity;

the condition for thermal shock treatment was: 15 periods of thermal shock between −190° C. and 140° C.

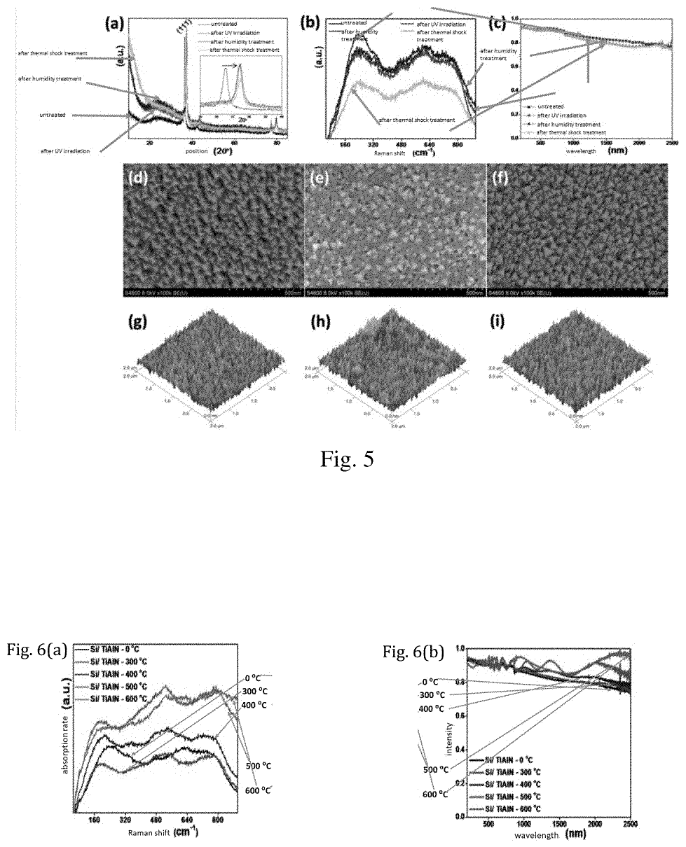

FIG. 5(a) and FIG. 5(b) are the XRD and Raman spectra of sample 1^{#}, being untreated and after various environmental treatments:

the XRD result shows that the diffraction peaks move towards a large angle after a series of treatments on the film, and the reason for the movement is considered via analysis to be due to the release of the inner stress in the film;

the Raman shift in the Raman spectrum does not change significantly, indicating that the structure of the film is stable.

FIG. 5(d)˜5(f) and FIG. 5(g)˜5(i) are respectively the scanning electron microscope characterization and the scanning probe morphology characterization of sample 1^{#}, being untreated and after various environmental treatments. By comparing the results of the surface morphology, the roughness and the similarity between the films being untreated and after various environmental treatments, with reference to the property determination results of the XRD peak position and intensity, the Raman shift and intensity, the light absorption rate shown in FIG. 5(a)˜5(c). It can be concluded that the structure and properties of the light absorption film are stable.

### Example 3 Performance Characterization of Light Absorption Film

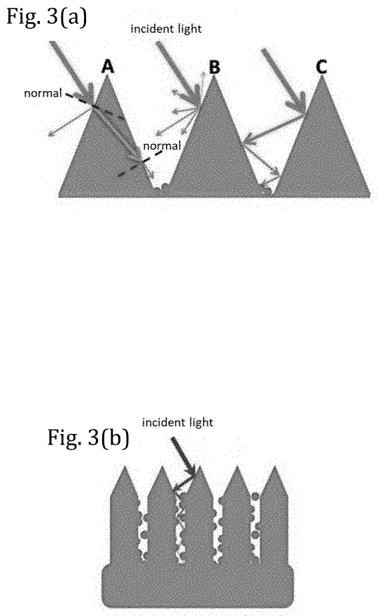

FIG. 3 is a schematic diagram showing the light absorption mechanism of the light absorption film in the present application, wherein (a) is a schematic diagram showing the process of incident light being entered from the surface of the film into the interior of the film, and (b) is a schematic diagram showing the process of light being reflected repeatedly between the grain boundaries to increase absorption.

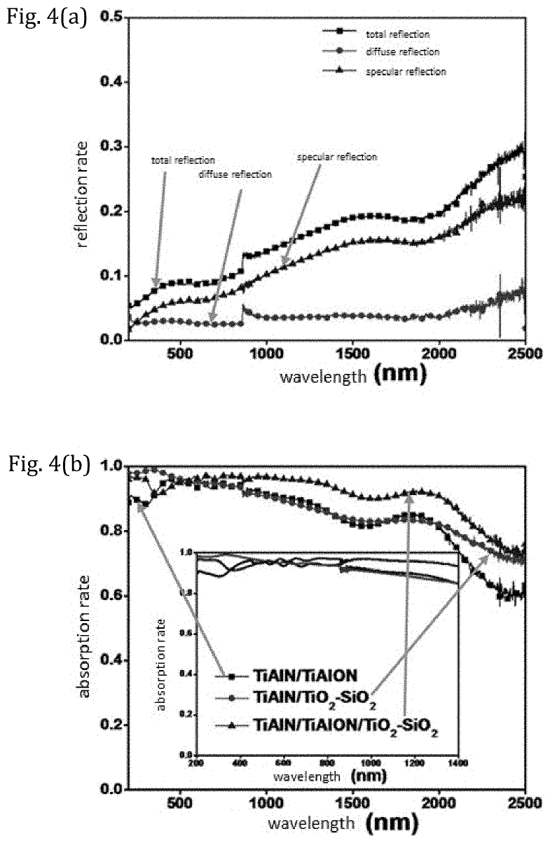

The reflection rates of total reflection, diffuse reflection and specular reflection of sample 1^{#} were determined, as shown in FIG. 4(a). It can be seen from the figure that in the total reflection, the intensity of the specular reflection is extremely low, and the light absorption rate is enhanced, indicating that the light absorption performance of the film prepared is good enough.

The light absorption performances of samples 6^{#}, 7^{#} and 8^{#} were tested, as shown in FIG. 4(b). It can be seen from the figure that the light absorption rate of sample 6^{#} is more than 0.92, and the light absorption rates of samples 7^{#} and 8^{#} are even higher, which can reach 0.95 or more. Within the wavelength range of 200˜1400 nm, the light absorption rate is more than 0.97.

Performance Characterization of Light Absorption Film after Environmental Treatment

FIG. 5(c) is the light absorption spectrum of sample 1^{#}, being untreated and after various environmental treatments. The result indicates that the light absorption rate of sample 1^{#} does not change significantly after being subjected to various environmental treatments, and is good in stability.

Performance Characterization of Light Absorption Film after Aging Treatment by Air Heating

The light absorption film sample 3^{#}, which was deposited on the surface of single crystal silicon, was used as a typical sample. The optical performance of the sample, after experiencing the aging treatments, heated in air at 300° C., 400° C., 500° C. and 600° C. for 7 hours, was tested, and the results are shown in FIG. 6.

FIG. 6(a) is the Raman spectrum of the film after aging, and the peaks at different positions in the Raman spectrum correspond to the absorption of titanium or aluminum ions as well as nitrogen ions to the photon energy.

FIG. 6(b) shows the light absorption rates of the film after the aging. The results show that the light absorption rate does not change substantially after the aging below 400° C., while the light absorption rate increases to 0.90 and 0.91 after aging at 500° C. and 600° C. respectively, indicating that the light absorption film has a high thermal stability in the air.

The above described are only several embodiments of the present application, which are not intended to be used to limit the present application in any form. Although the present application is disclosed with preferred embodiments as above, it does not mean that the present application is limited by them. Without departing from the technical solutions of the present application, any slight variations and modifications made by the skilled in the art who is familiar with this major by utilizing the above disclosures are all equal to the equivalent embodiments and fall into the scope of the technical solutions of the present application.

1-14. (canceled)

15. A light absorption film, comprising:
a titanium-aluminum-nitride film, and further comprising a bottom layer and an outer layer;
the bottom layer has a nano-layered structure, the outer layer has a columnar crystal structure, and the top of the columnar crystal structure is a conical surface; and
within a light wavelength range of 200 nm to 2500 nm, the light absorption film has an average light absorption rate α of not less than 0.89.

16. The light absorption film according to claim 15, wherein within a light wavelength range of 200 nm to 2500 nm, the light absorption film has an average light absorption rate α=0.89.

17. The light absorption film according to claim 15, wherein a thickness of the nano-layered structure ranges from 50 nm to 300 nm; a width of the crystal grain in the columnar crystal structure ranges from 30 nm to 100 nm, a thickness of a grain boundary between the columnar crystal grains ranges from 12 nm to 20 nm, and a thickness of a columnar crystal coating layer ranges from 800 nm to 2000 nm.

18. The light absorption film according to claim 17, wherein the thickness of the nano-layered structure is 100 nm; the width of the crystal grain in the columnar crystal structure is 50 nm, the thickness of the grain boundary between the columnar crystal grains is 17 nm, and the thickness of the columnar crystal coating layer is 1000 nm.

19. The light absorption film according to claim 15, wherein the light absorption film further comprises at least one antireflection layer.

20. The light absorption film according to claim 19, wherein the antireflection layer is at least one selected from the group consisting of TiAlON, TiO₂—SiO₂ and SiO₂.

21. The light absorption film according to claim 19, wherein within a light wavelength range of 200 nm to 2500 nm, the light absorption film has an average light absorption rate α of not less than 0.95.

22. The light absorption film according to claim 21, wherein within a light wavelength range of 200 nm to 2500 nm, the light absorption film has an average light absorption rate α=0.95.

23. A method for preparing a light absorption film having a titanium-aluminum-nitride film, and further having a bottom layer and an outer layer;
the bottom layer has a nano-layered structure, the outer layer has a columnar crystal structure, and the top of the columnar crystal structure is a conical surface; and
within a light wavelength range of 200 nm to 2500 nm, the light absorption film has an average light absorption rate α of not less than 0.89,
wherein a magnetron sputtering process is used to apply a co-sputtering to a titanium target and an aluminum target, comprising the following steps:
a1) introducing a gas mixture of nitrogen and an inert gas into a vacuum chamber, and applying a reverse sputtering to the targets to produce nitrides with a specific thickness, the nitriding treatment ranging from 3 min to 100 min; and
b1) after the nitriding treatment is completed, applying a normal sputtering to the targets to form the light absorption film on the surface of the substrate.

24. The method according to claim 23, wherein the inert gas in step a1) is at least one selected from the group consisting of nitrogen and inert gases;
the substrate in step b1) comprises at least one selected from the group consisting of metals, glasses, silicon wafers, single crystal materials and polymer materials.

25. The method according to claim 23, wherein the direct current or direct current pulse magnetron sputtering process is used to apply a co-sputtering to a titanium target and an aluminum target, comprising the following steps:
a2) introducing the inert gas at a flow rate ranged from 5 sccm to 200 sccm into a vacuum chamber having a vacuum degree ranging from 5.0×10⁻⁴ Pa to 9.0×10⁻⁴ Pa until the pressure in the vacuum chamber reaches a range from 0.01 Pa to 5 Pa, introducing nitrogen at a flow rate ranging from 1 sccm to 200 sccm, and applying a reverse sputtering to the targets to produce nitrides with a specific thickness, namely nitriding treatment, the nitriding treatment being ranging from 3 min to 100 min; and
b2) after the nitriding treatment is completed, applying a normal sputtering to the targets to form the light absorption film on the surface of the substrate.

26. The method according to claim 25, further comprising step a2) introducing argon gas at a flow rate ranging from 5 sccm to 100 sccm into a vacuum chamber having a vacuum degree of 7.0×10⁻⁴ Pa until the pressure in the vacuum apparatus reaches a range from 0.02 Pa to 3 Pa, then introducing nitrogen at a flow rate ranging from 2 sccm to 50 sccm, and applying a normal sputtering to the targets to form the light absorption film on the surface of a substrate, the time for the normal sputtering being ranging from 5 min to 60 min.

27. The method according to claim 23, further comprising step c): continuing to deposit at least one antireflection layer on the surface of the light absorption film to obtain a light absorption film comprising the antireflection layer.

28. The method according to claim 23, further comprising applying the light absorption film in the fields of solar energy conversion, heat control and extinction of optical devices.
